(19) United States
(12) Patent Application Publication
(10) Pub. No.: US 2004/0159832 A1
(43) Pub. Date: Aug. 19, 2004

(54) Spintonic devices and methods of making spintronic devices

(76) Inventor: Jonathan A. Hack, Gainesville, FL (US)

Correspondence Address: Min, Hsieh & Hack LLP, Suite 126, 125 University Ave, Palo Alto, CA, 94301, US

(21) Appl. No.: 10/765,671

(22) Filed: Jan. 26, 2004

Related U.S. Application Data
(60) Provisional application No. 60/443,878, filed on Jan. 31, 2003.

(51) Int. Cl. H01L 29/06

(52) U.S. Cl. 257/17

(57) ABSTRACT

In accordance with an embodiment of the invention, there is a material comprising an amorphous material and a dopant wherein the amorphous material displays magnetic behavior.

### CROSS-REFERENCE TO RELATED APPLICATION

The present application claims the benefit under 35 U.S.C. § 119(e) of provisional application Serial No. 60/443,878 filed Jan. 31, 2003, which is incorporated herein in its entirety.

### DESCRIPTION OF THE INVENTION

1. Field of the Invention

This application relates to an amorphous material which displays magnetic behavior. More particularly, this invention relates to using an amorphous material which displays magnetic behavior in spintronic devices.

2. Background of the Invention

Electrons have both charge and spin. Charge is generally described as the quantity of electricity associated with a particle, such as an electron. Spin is sometimes described as the angular momentum of a particle. The spin of a particle can be in either of two states, which by convention, are designated as the spin up state and the spin down state.

Conventional electronic devices use only the charge of the electron during operation. These devices have either ignored or have been unable to take advantage of electron spin. Indeed, in conventional electronic devices, the spins of the electrons are oriented at random.

It is known that the electron spins in a ferromagnetic material are aligned in a preferential direction. However, it has only recently been realized that in currents flowing from a ferromagnet into an ordinary metal the electrons retain their spin alignment so that spin alignment can be transported from one material to another.

However, it has not been possible to transfer spin alignment into semiconductors. One reason for this is that the only available ferromagnetic materials have been metals. The electrical conductivity of metal is significantly higher than the electrical conductivity of a semiconductor. This means that there are far more mobile electrons in the ferromagnetic metal than there are in the semiconductor and the transfer of electrons, which maintains spin alignment, are unsuccessful. For a large quantity of spin aligned electrons to be transferred from the ferromagnetic material into the semiconductor, the conductivity of the ferromagnet and the semiconductor must be closely matched. However, there has been no suitable material that fulfills this need.

It is accordingly a primary object of the invention to provide a material that displays ferromagnetic behavior that can be used in electronic devices to maintain spin alignment.

### SUMMARY OF THE INVENTION

In accordance with an embodiment of the invention, there is a material comprising an amorphous material and a dopant wherein the amorphous material displays magnetic behavior.

In another ambodiment of the invention there is an amorphous material and a dopant, wherein said amorphous material comprises a ferromagnetic semiconductor.

In another ambodiment of the invention there is a spin polarized electron device comprising an amorphous material, wherein the amorphous material comprises a magnetic semiconductor and a contact electrically connected to the amorphous material.

In another embodiment of the invention there is a method of making a spin polarized electron device comprising providing an amorphous material and contacting the amorphous material with at least one electrical contact, wherein the amorphous material comprises a magnetic semiconductor.

In another embodiment of the invention there is a contact comprising a substrate and a contact region formed in the substrate, wherein the contact region comprises an amorphous material, and wherein the amorphous material displays magnetic behavior.

In another embodiment of the invention there is a method of making a contact comprising patterning a contact region and forming an amorphous material in the contact region, wherein the amorphous material displays magnetic behavior.

In another embodiment of the invention there is a transistor comprising a source region, a drain region, a gate disposed between the source region and the drain region, wherein at least one of the source regions, drain regions, and gate comprises a magnetic material, and wherein the magnetic material comprises a magnetic semiconductor.

In another embodiment of the invention there is a transistor comprising a source region, a drain region, a gate insulator, a gate disposed between the source region and the drain region and a channel region, and a contact region. In this embodiment, at least one of the source region, drain region, gate insulator, gate, channel region, and contact comprises a magnetic material.

In another embodiment of the invention there is a method of fabricating a transistor. The method comprises forming a source region, forming a drain region, forming a gate insulator, forming gate between the source region and the drain region, forming a channel region, and forming a contact region. In the transistor, at least one of the source region, drain region, gate insulator, gate, channel region, and contact comprises a magnetic material.

In another embodiment of the invention there is a bipolar transistor comprising an emitter region, a base region, and a collector region. In the bipolar transistor at least one of the emitter region, base region, and collector region comprises a magnetic material.

In another embodiment of the invention there is a bipolar transistor comprising an emitter region, a base region, a collector region, and a contact region. In the bipolar transistor at least one of the emitter region, base region, collector region, and contact region comprises a magnetic material.

In another embodiment of the invention there is a method of making a bipolar transistor comprising forming an emitter region, forming a base region, and forming a collector region. In the method at least one of the emitter region, base region, and collector region comprises a magnetic material.

In another embodiment of the invention there is a magneto-resistive effect device comprising a pinning layer, a pinned layer, and a spacer layer disposed between the pinning layer and pinned layer. In the magneto-resistive effect device at least one of the pinning layer and pinned layer comprises an amorphous material.

In another embodiment of the invention there is a magneto-resistive effect device comprising a pinning layer, a pinned layer, a spacer layer disposed between the pinning layer and pinned layer, and a contact region connected to at least one of the pinning layer and pinned layer. In the magneto-resistive effect device at least one of the pinning layer, pinned layer, and contact region comprises an amorphous material.

In another embodiment of the invention there is a method of making a magneto-resistive effect device comprising forming a pinning layer, forming a pinned layer, and forming a spacer layer disposed between the pinning layer and pinned layer, and forming a contact. In the method at least one of the pinning layer, pinned layer, and contact comprises an amorphous material.

In another embodiment of the invention there is a method of generating polarized photons comprising providing a light source and directing the light source at an amorphous magnetic material. In the method the magnetic material comprises a magnetic semiconductor, wherein photons emitted from the amorphous magnetic material are polarized.

In another embodiment of the invention there is a light emitting device comprising an amorphous material, wherein the amorphous material comprises a magnetic semiconductor. The light emitting device also comprises a contact region comprising a contact electrically connected to the amorphous material.

In another embodiment of the invention there is a method of making a magnetic material comprising providing a material, doping the material with a dopant to adjust the conductivity of the material, and disrupting the material sufficiently to allow the material to display magnetic behavior.

Additional objects and advantages of the invention will be set forth in part in the description which follows, and in part will be obvious from the description, or may be learned by practice of the invention. The objects and advantages of the invention will be realized and attained by means of the elements and combinations particularly pointed out in the appended claims.

It is to be understood that both the foregoing general description and the following detailed description are exemplary and explanatory only and are not restrictive of the invention, as claimed.

The accompanying drawings, which are incorporated in and constitute a part of this specification, illustrate several embodiments of the invention and together with the description, serve to explain the principles of the invention.

### BRIEF DESCRIPTION OF THE DRAWINGS

FIG. 1 is a schematic representation of a magnetic material.

FIG. 2 is a schematic representation of a device for generating spin polarized electrons.

FIG. 3 is a schematic representation of a contact.

FIG. 4 is a schematic representation of a transistor.

FIG. 5 is a schematic representation of a Bipolar transistor.

FIG. 6 is a schematic representation of a magneto-resistive device.

FIG. 7 is a schematic representation of a device for generating polarized photons.

FIG. 8 is a schematic representation of a light emitting device.

### DESCRIPTION OF THE EMBODIMENTS

Reference will now be made in detail to the present embodiments of the invention, examples of which are illustrated in the accompanying drawings. Wherever possible, the same reference numbers will be used throughout the drawings to refer to the same or like parts.

An embodiment of the present invention is an amorphous material which displays magnetic behavior. In certain embodiments, the amorphous material displays ferromagnetic behavior and in other embodiments the amorphous material display antiferromagnetic behavior. The amorphous material may contain dopants to adjust the electrical conductivity. In certain embodiments, the electrical conductivity (or resistivity) of the amorphous material may be adjusted so that electrons transferred out of, or into the amorphous material maintain their spin alignment. The amorphous material may also contain active materials, which provide a predetermined function, such as to affect the coefficient of thermal expansion, refractive index, thermal conductivity, and electron mobility. Further, the amorphous material may also comprise inert materials.

In certain embodiments, the material comprising the amorphous material comprises a semiconductor material. Semiconductor materials may include, for example, silicon (Si), germanium (Ge), SiGe, hydrogenated amorphous silicon, gallium arsenide, materials selected from Group III and Group V elements, materials selected from Group II and Group VI elements, and organic semiconductor materials. When the material comprising the amorphous material comprises a semiconductor material, the amorphous material forms a magnetic semiconductor, such as a ferromagnetic semiconductor. At the same time, the amorphous material maintains its semiconducting properties.

In other embodiments, the material comprising the amorphous material comprises a metal. For example, the metal may be a refractory metal or transition metal. However, other metals are also contemplated. In this case, the resistivity of the amorphous material is adjusted by amorphization and/or dopants.

The amorphous material may comprise dopants to alter the electrical conductivity. When the material comprising the amorphous material comprises a semiconductor material, the dopants may include n-type and p-type dopants. For example, when the material comprising the amorphous material comprises Si, Ge, or SiGe, the dopants may include boron (B), phosphorous (P), and arsenic (As). However, other n-type and p-type dopants may be used depending on the application and/or the semiconductor material used, as will be known to one of ordinary skill in the art. When the material comprising the amorphous material comprises a metal, the dopants may include metals, semiconductors, or insulators.

The conductivity of the amorphous material can be adjusted to be in the range of between 1×10⁴ (Ω cm)⁻¹ to 1×10⁻¹⁰ (Ω cm)⁻¹. For example, in an embodiment where the material comprising the amorphous material comprises p-type Si, the resistivity of the amorphous material can be adjusted to be less than 5,000 Ω cm. Alternatively, the p-type amorphous Si can be adjusted to be between less than 100 Ω cm or less than 1 Ω cm. Alternatively, when the material comprising the amorphous material comprises n-type Si, the resistivity of the amorphous material can be adjusted to be less than 5,000 Ω cm, less than 100 Ω cm, less than 50 Ω cm, or less than 1 Ω cm.

Further, in an embodiment where the material comprising the amorphous material comprises p-type GaAs, the resistivity can be adjusted to be less than 1,000 Ω cm. Alternatively, when the material comprising the amorphous material comprises n-type GaAs, the resistivity can be adjusted to be between less than 1,000 Ω cm.

Alternatively, when the material comprising the amorphous material comprises a metal, the resistivity can be adjusted to be less than 5,000 Ω cm. Alternatively, the amorphous material can be adjusted to be between less than 100 Ω cm or less than 1 Ω cm

Other dopants may be used in conjunction with, or in place of those listed herein. For example, other dopants may include the transition metals, alkaline earth metals, alkali metals, and the rare earth elements. In certain embodiments, dopants may include at least one dopant selected from Mn, Fe, Co, and Ni. The amorphous material may also include at least one of hydrogen, carbon, carbon nanotubes, oxygen, and SiO₂.

The resistivity of the amorphous material can be adjusted so that the resistivity of the amorphous material is within eight orders of magnitude of the resistivity of the material adjacent to the amorphous material. In certain embodiments, the resistivity of the amorphous material can be adjusted to be within six, four, three, two, or one order of magnitude of the resistivity of the material adjacent to the amorphous material. And in certain embodiments, the material adjacent to the amorphous material may comprise a second amorphous material as described herein.

In an embodiment of the invention, the amorphous material also comprises a nanoparticles or a plurality of nanoparticles. The nanoparticles may have a length in their longest dimension in the range of 0.1-500 nm, 1-100 nm, or 2-50 nm. Further, the nanoparticles may be single crystals, polycrystalline, or nanotubes, such as carbon nanotubes. Moreover, the nanoparticels themselves may comprise dopants selected from the dopants listed herein. In certain embodiments, the nanoparticles comprise semiconductor materials, metals, and/or dopants, such as those listed herein.

Regions of the amorphous material are highly amorphous on a microscopic scale and have a high defect density. For example, the defect density in a region of the amorphous material may be greater than 1×10¹⁹ defects/cm³. Other regions of the amorphous material may have defect densities greater than 1×10²⁰ defects/cm³ or 1×10²¹ defects/cm³. Defect densities of the amorphous material can be measured, for example, using electron paramagnetic resonance by comparing the defect density of the amorphous material to the defect density of a known material. In the regions having high defect density, the average distance between defects can be between less than 10 nm, 5 nm, or 2 nm.

In the embodiments where the amorphous material comprises nanoparticles, a substantial number of defects reside at the interface between the nanoparticles and the surrounding amorphous material. In these embodiments, the amorphous material which surrounds the nanoparticles is regarded as an amorphous matrix.

Numerous methods exist to fabricate the amorphous material of the present invention. Some exemplary methods include, ion implantation, laser ablation, spark processing, anodic etching, evaporation using an electron beam, glow-discharge techniques, CVD techniques, thermal evaporation, melt quenching, sol-gel processing, electrolytic deposition, reaction amorphization, irradiation, pressure induced amorphization, solid state diffusion amorphization, and sputtering. Other methods of forming amorphous materials will be known to one of ordinary skill in the art and will not be discussed herein. However, with sufficiently high amorphization, the material is converted into an amorphous material that displays magnetic behavior, such as ferromagnetic or antiferromagnetic behavior.

In one exemplary embodiment, ion implantation is used to form the amorphous material that displays magnetic behavior. Ions are implanted into a material using conventional methods at a dose sufficient to cause amorphization of the material. With sufficiently high amorphization, the material is converted into an amorphous material that displays magnetic behavior.

In one exemplary embodiment, silicon ions may be implanted into silicon at a dose sufficient to cause amorphization in the silicon. With sufficiently high amorphization, the silicon will display magnetic behavior, such as ferromagnetic behavior. In certain embodiments, after implantation the ion implanted silicon can be annealed so that silicon nanocrystals form in the amorphous material.

Other ions, such as B, P, As, Ge, Ne, Ar, Ga, As, H, He, Mn, Fe, Co, Ni, transition metals, alkaline earth metals, alkali metals, and the rare earth elements can be implanted into the material at a dose sufficient to cause amorphization. With sufficiently high amorphization, the material displays magnetic behavior. By way of another example, and for illustrative purposes, Ne+ and/or Ar+ ions may be implanted at ion doses of greater than 1×10¹⁴ cm⁻² with an ion energy of at least 30 KeV. In certain embodiments, the ion dose may be greater than 1×10¹⁷ cm⁻².

In another exemplary embodiment, large numbers of defects can be formed by nucleating and growing nanoparticles on a first material and covering the nanoparticles and the exposed first material with an additional material, such as the first material or with a second material. In this case, the number of defects present at the interface between the nanoparticles and the surrounding material will be sufficient to alter the material so that the material displays magnetic behavior. In an embodiment, the nucleated and grown amorphous material may also be further amorphized by ion implantation.

Alternatively, nanotubes may be dispersed in a material. The interface between the nanotubes and the surrounding material will comprise a large number of defects sufficiently high to alter the material so that the material displays magnetic behavior.

The conductivity of the material comprising the amorphous material may be adjusted. In certain embodiments, the conductivity may be adjusted before the process of amorphizing the material. Alternatively, the conductivity may be adjusted during amorphization or the amorphous material may be adjusted after the amorphization. Adjustment of the conductivity may by be accomplished by any means known to one of ordinary skill in the art. Exemplary methods of adjusting the conductivity include, but are not limited to doping using ion implantation or diffusion. Alternatively, the doping can be accomplished by hydrogenating at least a portion of the amorphous material.

In certain embodiments, the conductivity of the amorphous material is adjusted to be within five orders of magnitude of the conductivity of the material adjacent to the amorphous material. In other embodiments, the conductivity is adjusted to be within three, two or one order of magnitude of the conductivity of the material adjacent to the amorphous material. The material adjacent to the amorphous material may be either in electrical contact, physical contact or both. By adjusting the conductivity of the amorphous material or the adjacent material, large numbers of spin polarized (aligned) electrons can be transferred to and from the amorphous material to the material adjacent to the amorphous material. This is in contrast to the condition where the material transferring spin polarized electrons is a conventional ferromagnetic metal. In this case, the conductivity of conventional ferromagnetic metals is much greater than the conductivity of the adjacent material. For example, in the case of conventional ferromagnetic iron adjacent to a semiconductor, there are substantially more mobile electrons in the iron than in the semiconductor. Very few of the mobile electrons are capable of being transferred from the iron to the adjacent semiconductor material.

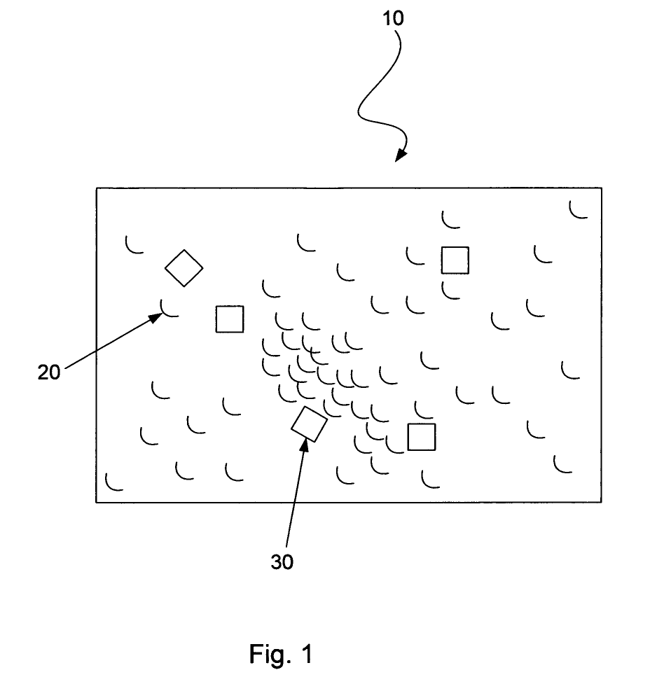

FIG. 1 shows a schematic representation of an amorphous material 10, described herein. FIG. 1 shows defects 20 and nanoparticles 30 in amorphous material 10. The conductivity of the amorphous material 10 can be adjusted, for example by doping with dopants (not shown).

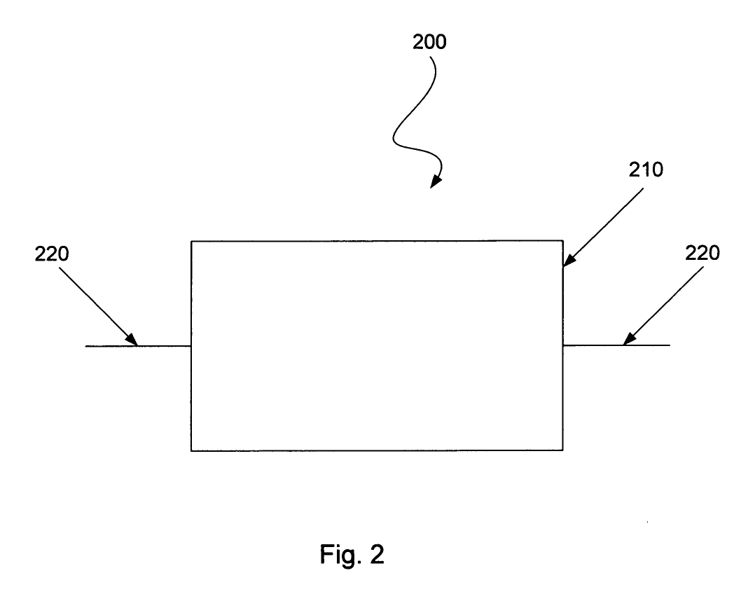

FIG. 2 shows a schematic representation of a device 200 for generating spin polarized electrons. Device 200 comprises amorphous material 210 and at least one contact 220 electrically connected to amorphous material 210. The conductivity of the amorphous material 210 can be adjusted, for example by doping with dopants. Dopants can be used to adjust the electrical conductivity of amorphous material 210 to be within five, three two or one order of magnitude of material adjacent the amorphous material. The conductivity of the adjacent material may also be adjusted. In certain embodiments, amorphous material 210 also comprises nanoparticles.

An embodiment of the present invention includes methods of making a device for generating spin polarized electrons, as shown for example in FIG. 2. The method of making device 200 comprises providing an amorphous material (the amorphous material may further comprise dopants and/or nanoparticles). The method of the present embodiment also includes electrically contacting the amorphous material with at least one contact.

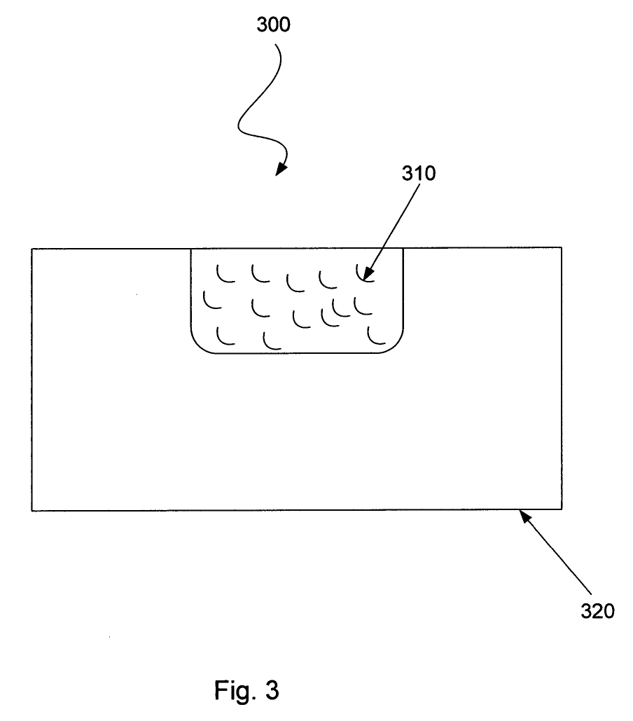

FIG. 3 shows a schematic representation of a contact 300, another embodiment of the present invention. FIG. 3 shows a contact region 310 comprising an amorphous material disposed in substrate 320. Substrate 320 may be any region of a device in which spin polarized electrons are transferred. For example, substrate 320 may be a source, a drain, or a gate electrode of a transistor. In general, contact 300 may be used to transfer spin polarized electrons into any device.

Contact region 310 of contact 300 may be fabricated from the amorphous material of the present invention. In this case, dopants and/or nanoparticles may be added to the amorphous material to adjust the conductivity to be within five, three, two or one order of magnitude of the adjacent material. The conductivity of the adjacent material may also be adjusted.

In one embodiment, contact region 310 comprises a semiconductor material amorphized that has been amorphized sufficiently high to display magnetic behavior. In another embodiment, the contact region 310 comprises a metal, such as a refractory metal or a transition metal that has been amorphized sufficiently high to display magnetic behavior. Other metals, alloys, nitrides or oxides of metals, of suicides may also be used to form contact region 310.

When forming the amorphous material of contact 310, substrate 320 may be masked by conventional masking techniques. The amorphous material is fabricated in predetermined regions defined by the mask.

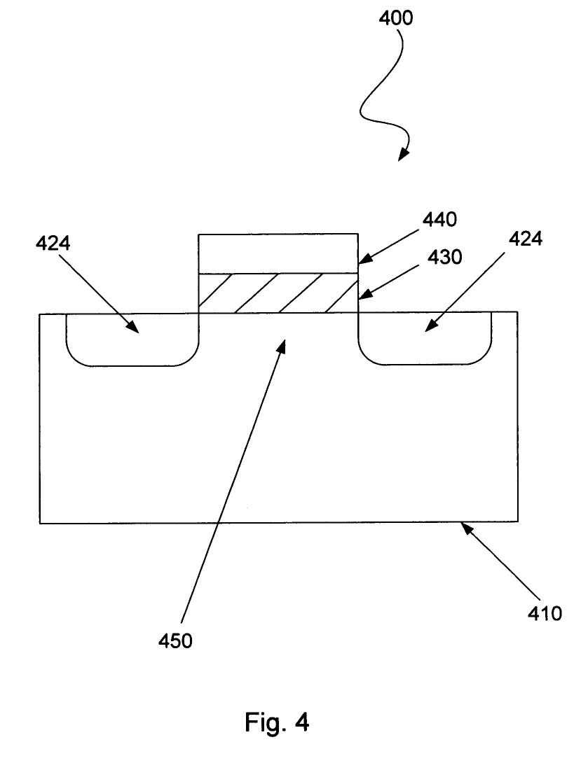

Another embodiment of the present invention is a transistor 400, as shown in FIG. 4. FIG. 4 shows a schematic representation of transistor 400 comprising substrate 410, source region 422, drain region 424, gate insulator 430, gate 440, and channel region 450. Transistor 400 also comprises a contact (not shown) electrically connected to at least one of comprising substrate 410, source region 422, drain region 424, gate insulator 430, gate 440, and channel region 450. In one embodiment of transistor 400, at least one of the source region 422, drain region 424, gate insulator 430, gate 440, channel region 450 and the contact comprises an amorphous material which displays magnetic behavior. Dopants and/or nanoparticles may be added to the amorphous material to adjust the conductivity to be within five, three, two or one order of magnitude of the adjacent material. The conductivity of the adjacent material may also be adjusted.

An embodiment of the present invention includes a method of fabricating a transistor, such as transistor 400. Conventional methods may be used to define and fabricate the structures of transistor 400, such as, source region 422, drain region 424, gate insulator 430, gate 440, channel region 450, and contacts. The material comprising the amorphous material may be formed to display magnetic behavior while the structures of transistor 400 are formed, or it may be formed to display magnetic behavior subsequent to formation of the structures. Dopants and/or nanoparticles may be added to the amorphous material to adjust the conductivity to be within five, three, two or one order of magnitude of the adjacent material. The conductivity of the adjacent material may also be adjusted.

For example, source region 422 and drain region 424 may be formed of a semiconductor material and subsequently amorphized by ion implantation. Alternatively, the material that will form source region 422 and drain region 424 may be formed as an amorphous material by deposition techniques when source region 422 and drain region 424 are formed. Similarly, other structures of transistor 400, such as contacts, gate insulator 430, gate 440, and channel region 450 may be formed of the amorphous material during their formation, or the structures may be amorphized subsequent to their formation. Dopants and/or nanoparticles may be added to the amorphous material to adjust the conductivity to be within five, three, two or one order of magnitude of the adjacent material. The conductivity of the adjacent material may also be adjusted.

In another exemplary embodiment, the contacts of transistor 400 may comprise a metal, as described herein. In this case, the metal may be amorphized sufficiently high to display magnetic behavior. Dopants and/or nanoparticles may be added to the amorphous material to adjust the conductivity to be within five, three, two or one order of magnitude of the adjacent material. In certain embodiments, the adjacent material may also comprise an amorphous material amorphized sufficiently high to display magnetic behavior. Dopants and/or nanoparticles may be added to the amorphous material to adjust the conductivity to be within five, three, two or one order of magnitude of the contact material. The conductivity of the adjacent material may also be adjusted.

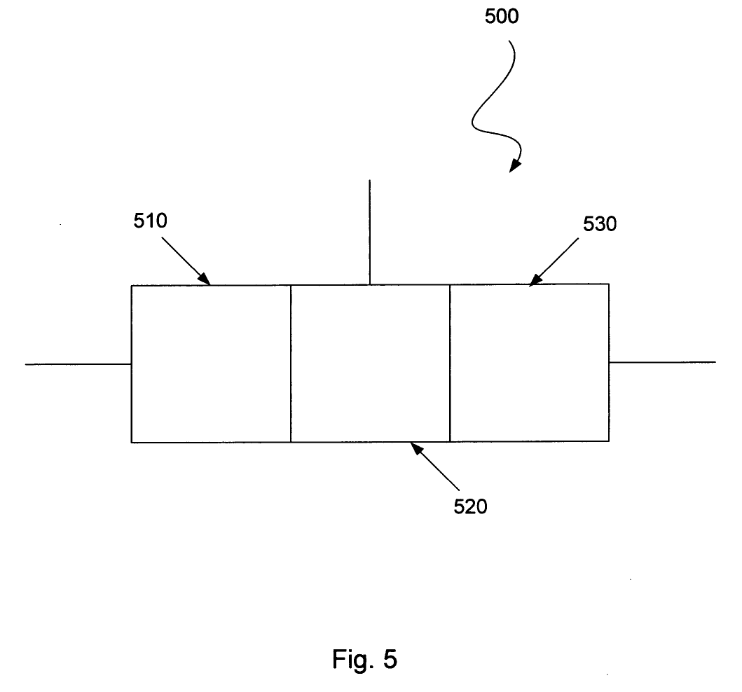

Another embodiment of the present invention is a Bipolar transistor 500 as shown in FIG. 5. FIG. 5 is a schematic representation of Bipolar transistor 500 comprising an emitter 510, a base 520, and a collector 530. Bipolar transistor 500 also comprises contacts formed either in or on at least one of emitter 510, base 520 and collector 530. In this embodiment, at least one of the emitter 510, base 520, collector 530, and the contacts comprises an amorphous material which displays magnetic behavior. Dopants and/or nanoparticles maybe added to the amorphous material to adjust the conductivity to be within five, three, two or one order of magnitude of the adjacent material. The conductivity of the adjacent material may also be adjusted.

In another exemplary embodiment, the contacts of the Bipolar transistor 500 may comprise a metal, as described herein. In this case, the metal may be amorphized sufficiently high to display magnetic behavior. Dopants and/or nanoparticles may be added to the amorphous material to adjust the conductivity to be within five, three, two or one order of magnitude of the adjacent material. In certain embodiments, the adjacent material may also comprise an amorphous material amorphized sufficiently high to display magnetic behavior. Dopants and/or nanoparticles may be added to the amorphous material to adjust the conductivity to be within five, three, two or one order of magnitude of the contact material.

An embodiment of the present invention includes a method of fabricating a Bipolar transistor, such as Bipolar transistor 500. Conventional methods may be used to define and fabricate the structures of Bipolar transistor 500, such as emitter 510, base 520, and collector 530, or contacts. The material comprising the amorphous material may be formed to display magnetic behavior while forming the structures of Bipolar transistor 500 or after the structures are formed.

For example, emitter 510 and collector 530 may be formed of a semiconductor material and subsequently amorphized by ion implantation. Alternatively, the material that will form the emitter 510 and collector 530 may be formed as an amorphous material when emitter 510 and collector 530 are formed. Similarly, other structures of Bipolar transistor 500, such as the contacts may be forrmed of the amorphous material during their formation or subsequent thereto. In certain embodiments, the contacts may comprise a metal. Dopants and/or nanoparticles may be added to the amorphous material of the structures to adjust the conductivity to be within five, three, two or one order of magnitude of the adjacent material. The conductivity of the adjacent material may also be adjusted.

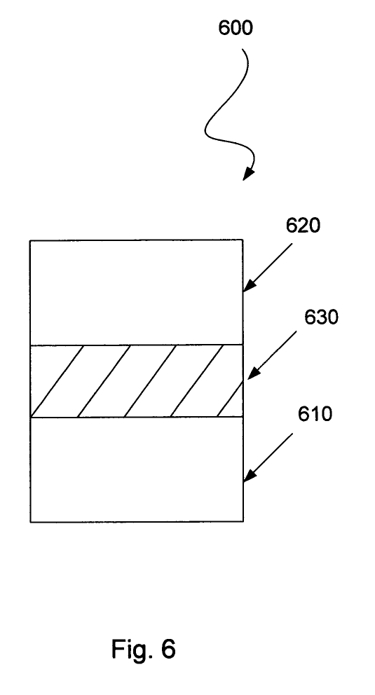

Another embodiment of the present invention is a magneto-resistance device 600, as shown in FIG. 6. FIG. 6 is a schematic representation of magneto-resistance device 600 comprising a pinning layer 610, a pinned layer 620 and a spacer material 630 disposed between the pinning layer 610 and the pinned layer 620. Device 600 may also comprise contacts formed either in or on at least one of pinning layer 610 or pinned layer 620. In magneto-resistance device 600 at least one of the pinning layer 610, the pinned layer 620, and the contacts comprises an amorphous material which displays either ferromagnetic or antiferromagnetic behavior. Dopants and/or nanoparticles may be added to the amorphous material of the structures to adjust the conductivity to be within five, three, two or one order of magnitude of the adjacent material. The conductivity of the adjacent material may also be adjusted.

An embodiment of the present invention includes a method of fabricating a magneto-resistive device, such as device 600. Conventional methods, such as masking and deposition techniques may be used to define and fabricate the structures of device 600, such as pinning layer 610, pinned layer 620, spacer material 630, and the contacts. The material comprising the amorphous material may be amorphised sufficiently high to display magnetic behavior while forming the structures of device 600 or after the structures are formed.

For example, pinning layer 610 may be formed and subsequently amorphized by ion implantation. Alternatively, the material that will form pinning layer 610 and pinned layer 620 may be formed as an amorphous material by deposition techniques when pinning layer 610 and pinned layer 620 are formed.

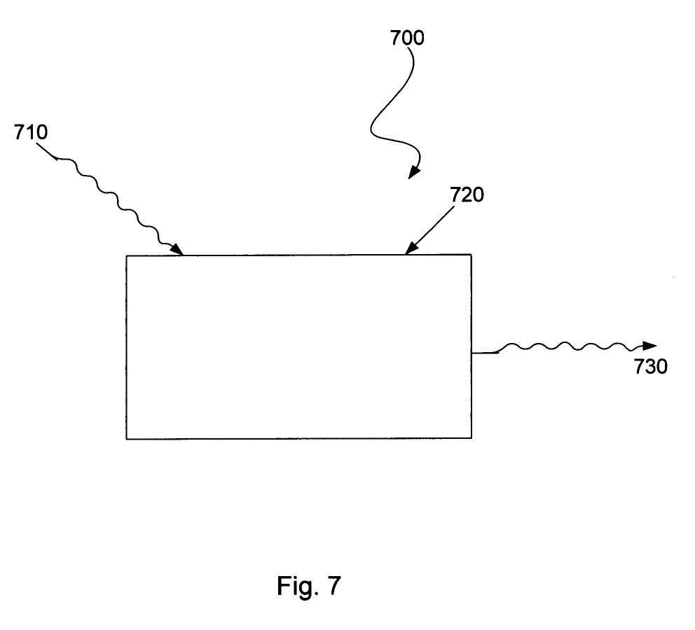

Another embodiment of the present invention includes a method of producing polarized photons, as shown in FIG. 7. In FIG. 7, a light source 710 is provided. Light source 710 may be, for example, a laser, a LED, a UV lamp, or another light source suitable for photoluminescence. Light from light source 710 is directed at an amorphous material 720, which comprises a magnetic semiconductor material described herein. Photons 730 emitted from the magnetic material 720 are polarized. In certain embodiments, magnetic material 720 comprises nanoparticles and/or dopants.

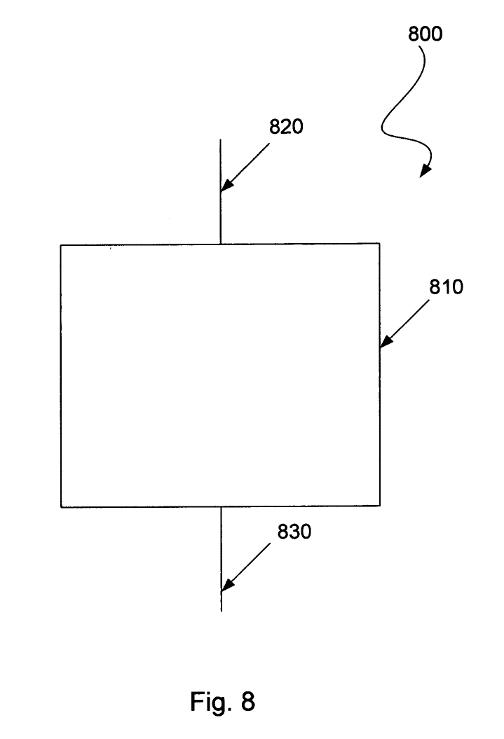

Another embodiment of the present invention includes a light emitting device 800, as shown in FIG. 8. Light emitting device 800 comprises a light emitting material 810, such as an amorphous material described herein. In certain embodiments, amorphous material 810 comprises nanoparticles and/or dopants. Light emitting device 800 also comprises at least one contact 820 electrically connected to the magnetic material 810.

Alternatively, contacts 820 may comprise an amorphous material which displays magnetic behavior. In this embodiment, the light emitting material 810 may or may not be a magnetic material.

In certain embodiments, the amorphous material of either the light emitting material 810 and/or the contacts 820 comprise a nanoparticle and/or dopants.

An embodiment of the present invention includes a method of fabricating a light emitting device, such as device 800. In this embodiment, contacts 820 are formed either in or on the light emitting material 810. In embodiments where the light emitting material is an amorphous material that displays magnetic behavior, the amorphous material is formed and contacts 820 are contacted to material 810.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A material comprising:
an amorphous material, wherein the amorphous material displays magnetic behavior; and
a dopant.

2. A material according to claim 1, wherein the amorphous material includes a nanoparticle.

3. A material according to claim 1, wherein said dopant comprises a dopant selected from n-type and p-type dopants.

4. A material according to claim 2, wherein said dopant comprises a dopant selected from n-type and p-type dopants.

5. A material according to claim 1, wherein said dopant comprises a dopant selected from transition metals, alkaline earth metals, alkali metals, and rare earth elements.

6. A material according to claim 2, wherein said dopant comprises a dopant selected from transition metals, alkaline earth metals, alkali metals, and rare earth elements.

7. A material according to claim 1, wherein said amorphous material has a defect density of at least 1×10²⁰ defects/cm³.

8. A material according to claim 2, wherein said magnetic amorphous has a defect density of at least 1×10²⁰ defects/cm³.

9. A material according to claim 1, wherein said amorphous material comprises silicon.

10. A material according to claim 2, wherein said amorphous material comprises silicon.

11. A material according to claim 10, wherein said nanoparticles comprise silicon.

12. A material according to claim 1, wherein said amorphous material comprises a material selected from III-V semiconductors or II-VI semiconductors.

13. A material according to claim 2, wherein said amorphous material comprises a material selected from III-V semiconductors or II-VI semiconductors.

14. A material according to claim 1, wherein said amorphous material comprises a metal.

15. A material according to claim 2, wherein said amorphous material comprises a metal.

16. A material according to claim 2, wherein said nanoparticles comprise a material selected from at least one of a Group III element and a Group V element.

17. A material according to claim 2, wherein said nanoparticles comprise a material selected from at least one of a Group II element and a Group V1 element.

18. A material comprising:
an amorphous material, wherein said amorphous material comprises a ferromagnetic semiconductor; and
a dopant.

19. A material according to claim 18, wherein the amorphous material includes a nanoparticle.

20. A material according to claim 18, wherein said dopant comprises a dopant selected from n-type and p-type dopants.

21. A material according to claim 19, wherein said dopant comprises a dopant selected from n-type and p-type dopants.

22. A material according to claim 18, wherein said dopant comprises a dopant selected from transition metals, alkaline earth metals, alkali metals, and rare earth elements.

23. A material according to claim 19, wherein said dopant comprises a dopant selected from transition metals, alkaline earth metals, alkali metals, and rare earth elements.

24. A material according to claim 18, wherein said amorphous material has a defect density of at least 1×10²⁰ defects/cm³.
